(19) United States
(12) Patent Application Publication
(10) Pub. No.: US 2016/0276933 A1
(43) Pub. Date: Sep. 22, 2016

(54) POWER SUPPLY CIRCUIT

(71) Applicant: KABUSHIKI KAISHA TOSHIBA, Tokyo (JP)

(72) Inventors: Hiroshi SAITO, Ota Tokyo (JP); Yuichi GOTO, Hiratsuka Kanagawa (JP)

(21) Appl. No.: 15/059,158

(22) Filed: Mar. 2, 2016

(30) Foreign Application Priority Data
Mar. 16, 2015 (JP) 2015-052570

(51) Int. Cl. H02M 3/158; H03K 5/24; H03K 19/0175

(52) U.S. Cl. CPC H02M 3/158; H03K 19/017509; H03K 5/24

(57) ABSTRACT

A power supply circuit, such as a DC-DC converter includes a first transistor connected to an input voltage node, a second transistor connected between the first transistor and a reference voltage node, a first gate control circuit to control a gate voltage of the first transistor, a capacitor connected between first and second power supplying nodes of the first gate control circuit, and a first control circuit configured to charge the capacitor at least while the second transistor is in a non-conducting state.

### CROSS-REFERENCE TO RELATED APPLICATION

This application is based upon and claims the benefit of priority from Japanese Patent Application No. 2015-052570, filed Mar. 16, 2015, the entire contents of which are incorporated herein by reference.

### FIELD

An embodiment described herein relates generally to a power supply circuit, such as a DC-DC converter.

### BACKGROUND

In a DC-DC converter, a high side transistor and a low side transistor are alternately switched to drive an inductor. After electric energy is converted into magnetic energy, the magnetic energy is converted into electric energy by an output capacitor, and thus a change in a DC voltage level is performed.

When an NMOS transistor is used as the high side transistor, a voltage higher than an input voltage is applied to a gate control circuit that controls the gate of the high side transistor, and thus a bootstrap capacitor is usually connected between two power supplying nodes of the gate control circuit.

In a light load state in which a load of the DC-DC converter is small, the high side transistor and the low side transistor perform an intermittent operation, whereby power consumption is reduced. In this case, a charged voltage of a bootstrap capacitor is monitored such that the charged voltage of the bootstrap capacitor is not decreased beyond a desirable level, and when the charged voltage is equal to or lower than a predetermined voltage, the low side transistor is turned on, thereby charging the bootstrap capacitor again. However, during intermittent operation, turning on the low side transistor increases wasteful power consumption.

### DESCRIPTION OF THE DRAWINGS

FIG. 1 is a circuit diagram of a DC-DC converter according to an embodiment.

FIG. 2 is a timing diagram during a normal operation of the DC-DC converter according to an embodiment.

FIG. 3 is a timing diagram when a load is in a state of a light load and when an input voltage is higher than an output voltage by a first voltage.

FIG. 4 is a timing diagram during a light load state and an input voltage is equal to or lower than an output voltage by a first voltage.

### DETAILED DESCRIPTION

An embodiment provides a DC-DC converter that may charge a bootstrap capacitor with low power consumption during a light load state.

In general, a power supply circuit, such as, for example, a DC-DC converter, includes a first transistor connected to an input voltage node, a second transistor connected between the first transistor and a reference voltage node (e.g., a ground node), a first gate control circuit having a first power supplying node and a second power supplying node and configured to control a gate voltage of the first transistor, a capacitor connected between the first and second power supplying node, and a first control circuit configured to charge the capacitor at least while the second transistor is in a non-conducting state.

In general, according to one embodiment, a DC-DC converter includes: a first transistor that is connected between a node of an input voltage and one terminal of an inductor; a second transistor that is connected between the one terminal of the inductor and a reference voltage node; a first gate control circuit that controls a gate voltage of the first transistor; a capacitor that is connected between first and second power supplying nodes of the first gate control circuit; a first detection circuit that detects whether or not a voltage difference between the input voltage and a voltage on the other terminal side of the inductor is equal to or lower than a first voltage; and a first charging control circuit that, when the first detection circuit detects the voltage difference is higher than the first voltage, in a case that a charged voltage of the capacitor is equal to or lower than a predetermined voltage, charges the capacitor, while the second transistor is turned off.

Hereinafter, an embodiment will be described with reference to the drawings. The following embodiment will be described with a focus on a characteristic configuration and an operation of a DC-DC converter, but configurations and operations which are omitted in the following description may exist in the DC-DC converter. However, these configurations and operations which are omitted but still apparent to those of ordinary skill in the art are also included in the scope of the present disclosure.

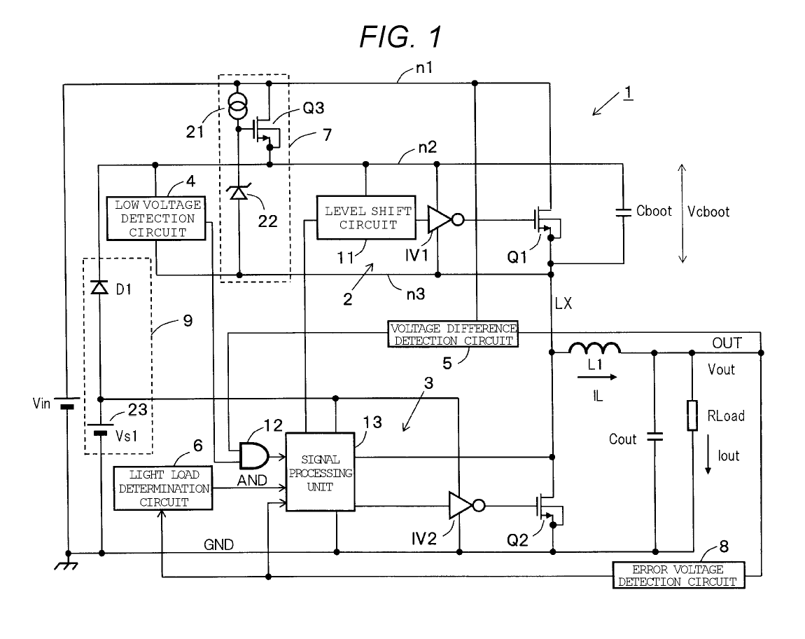

FIG. 1 is a circuit diagram of a DC-DC converter 1 according to an embodiment. The DC-DC converter 1 includes a bootstrap capacitor Cboot, a high side transistor (first transistor) Q1, a low side transistor (second transistor) Q2, a first gate control circuit 2, a second gate control circuit 3, a low voltage detection circuit (third detection circuit) 4, a voltage difference detection circuit (first detection circuit) 5, a light load determination circuit (determination circuit) 6, a first charging control circuit (a first control circuit) 7, an error voltage detection circuit (second detection circuit) 8, and a second charging control circuit 9 (a second control circuit).

The high side transistor Q1 is connected between a node n1 of an input voltage Vin of the DC-DC converter 1 and a terminal LX of an inductor L1. The high side transistor Q1 is, for example, an NMOS transistor. By configuring the high side transistor Q1 with using an NMOS transistor, an ON resistance may be reduced and efficiency increased, compared to configuring the high side transistor Q1 with using a PMOS transistor. However, in order to completely turn on an NMOS transistor, it is required that a gate-source voltage is large, and that a gate voltage of the NMOS transistor is higher than a drain voltage thereof. Since the drain voltage is the input voltage Vin of the DC-DC converter 1, it is necessary to generate a gate voltage higher than the input voltage Vin. Therefore, the bootstrap capacitor Cboot is connected between a high side power supply node (first power supplying node) n2 and a high side ground node (second power supplying node) n3 of the first gate control circuit 2 that controls a gate voltage of the high side transistor Q1, and a power supply voltage higher than the input voltage Vin is supplied to the first gate control circuit 2.

The first gate control circuit 2 includes a level shift circuit 11, and an inverter IV1 that inverts an output voltage of the level shift circuit 11 and outputs the inverted voltage. An output voltage of the inverter IV1 becomes the gate voltage of the high side transistor Q1.

The low side transistor Q2 is connected between the terminal LX of the inductor L1 and a low side ground node (reference voltage node) GND. The low side transistor Q2 is, for example, an NMOS transistor.

The second gate control circuit 3 is connected to the gate of the low side transistor Q2. The second gate control circuit 3 includes a logical operation unit 12, a signal processing unit 13, and an inverter IV2. The logical operation unit 12 will be described later, but is depicted in FIG. 1 as an AND operation unit. The signal processing unit 13 generates control signals for both of the first gate control circuit 2 and the second gate control circuit 3. The inverter IV2 inverts the control signal from the signal processing unit 13 and generates a gate voltage of the low side transistor Q2. In addition, the control signal for the first gate control circuit 2, which is generated by the signal processing unit 13, is level-shifted by the level shift circuit 11 and thereafter is input to the inverter IV1.

An output terminal OUT of the DC-DC converter 1 at which an output voltage Vout is supplied is connected to the other terminal of the inductor L1, and an output capacitor Cout and a load Rload are connected (or connectable) between the output terminal OUT and the low side ground node GND. It is assumed that a size of the load Rload is variable or can be variable.

The voltage difference detection circuit 5 detects whether or not a voltage difference between the input voltage Vin and the output voltage Vout is equal to or lower than a first voltage (e.g., a predetermined voltage), and outputs a detection signal that indicates or otherwise corresponds to whether the difference between input voltage Vin and output voltage Vout is equal to or lower than the first voltage or not. The first voltage is, for example, 5 V. The detection signal that is output from the voltage difference detection circuit 5 is supplied to the other input node of the logic operation unit 12. For example, the detection signal becomes a high potential, when the voltage difference is equal to or lower than the first voltage.

The low voltage detection circuit 4 is connected between both electrodes of the bootstrap capacitor Cboot, detects whether or not a charged voltage of the bootstrap capacitor Cboot is equal to or lower than a second voltage, and supplies the detection signal indicating whether or not the charged voltage of the bootstrap capacitor is equal to or lower than the second voltage to one input node of the logic operation unit 12. For example, when the charged voltage of the bootstrap capacitor Cboot is equal to or lower than the second voltage, the low voltage detection circuit 4 makes the detection signal have a high potential. Here, the second voltage is a voltage at which it is required to begin recharging of the bootstrap capacitor Cboot, and more specifically, is a voltage that does not guarantee an ON operation of the high side transistor Q1. The second voltage is a voltage that is determined by characteristics of the high side transistor Q1, or the like.

The logic operation unit 12 is, for example, an AND gate that outputs a logical product signal of two input nodes. An output of the logic operation unit 12 has a high potential, when a voltage difference between the input voltage Vin and the output voltage Vout is equal to or lower than the first voltage and the charged voltage of the bootstrap capacitor Cboot is equal to or lower than the second voltage. The output signal of the logic operation unit 12 is input to the signal processing unit 13.

The logic operation unit 12 need not always be or otherwise include an AND gate. The logic operation unit 12 may be configured by combining various types of logic gates.

The error voltage detection circuit 8 detects an error voltage that indicates a voltage difference between the voltage Vout on the other terminal side of the inductor L1 and a reference output voltage. When the error voltage is small, the error voltage indicates that the output voltage Vout is close to the reference output voltage, and it is possible to determine that the load Rload is light.

The light load determination circuit 6 determines whether the DC-DC converter 1 is in the light load state (according as to whether the load Rload is light or not), based on the error voltage. More specifically, the light load determination circuit 6 determines that a load is in the light load state, when the error voltage is equal to or lower than a predetermined voltage.

The signal processing unit 13 generates a control signal for the high side transistor Q1 and a control signal for the low side transistor Q2, based on a voltage on the first terminal LX side of the inductor L1, the output signal of the logic operation unit 12, the output signal of the light load determination circuit 6, and the error voltage. For example, when the light load determination circuit 6 determines that a load is in a light load state, the signal processing unit 13 generates a control signal that turns off together the high side transistor Q1 and the low side transistor Q2.

In this way, at the time of a light load, the high side transistor Q1 and the low side transistor Q2 are turned off together, and thereby power consumption is reduced. However, when the charged voltage of the bootstrap capacitor Cboot is sufficiently lowered, charging of the bootstrap capacitor Cboot is performed, using the first charging control circuit 7 or the second charging control circuit 9, as will be described later. The second charging control circuit 9 instantaneously turns on the low side transistor Q2.

When the voltage difference detection circuit 5 determines that the voltage difference is higher than the first voltage, the first charging control circuit 7 charges a capacitor in a state in which the second transistor is turned off.

The first charging control circuit 7 includes a current source 21, a Zener diode (constant voltage source) 22, and a third transistor Q3, as a more specific, but non-limiting example. The current source 21 is connected between an application node of the input voltage Vin and the gate of the third transistor Q3. The Zener diode 22 is connected between the gate of the third transistor Q3 and the high side ground node n3. That is, the current source 21 and the Zener diode 22 are connected in series between the application node of the input voltage Vin (that is, the node where the input voltage Vin is applied) and the high side ground node n3. The third transistor Q3 is, for example, an NMOS transistor, a drain thereof is connected to the application node of the input voltage Vin, and a source thereof is connected to the high side power supply node n2. The third transistor Q3 operates in an active region (or linear operation mode). When a voltage difference between the application node of the input voltage Vin and the high side power supply node n2 is equal to or higher than a predetermined voltage, the third transistor Q3 makes a current flow from the application node of the input voltage Vin to the high side power supply node n2, whereby charging of the bootstrap capacitor Cboot is performed.

The second charging control circuit 9 is connected between the high side power supply node n2 and the low side ground node GND. The second charging control circuit 9 charges a capacitor when the low side transistor Q2 is turned on. The second charging control circuit 9 includes a diode D1 and a DC power supply 23 which are connected in series between the high side power supply node n2 and the low side ground node GND. An anode of the diode D1 is connected to the DC power supply 23, and a cathode of the diode D1 is connected to the high side power supply node n2.

A voltage level Vs1 of the DC power supply 23 is higher than a voltage level Vcboot1+Vgs of the Zener diode 22. According to this, when the charged voltage Vcboot1 of the bootstrap capacitor Cboot is decreased to a voltage level of the Zener diode 22, the bootstrap capacitor Cboot is recharged with using the first charging control circuit 7.

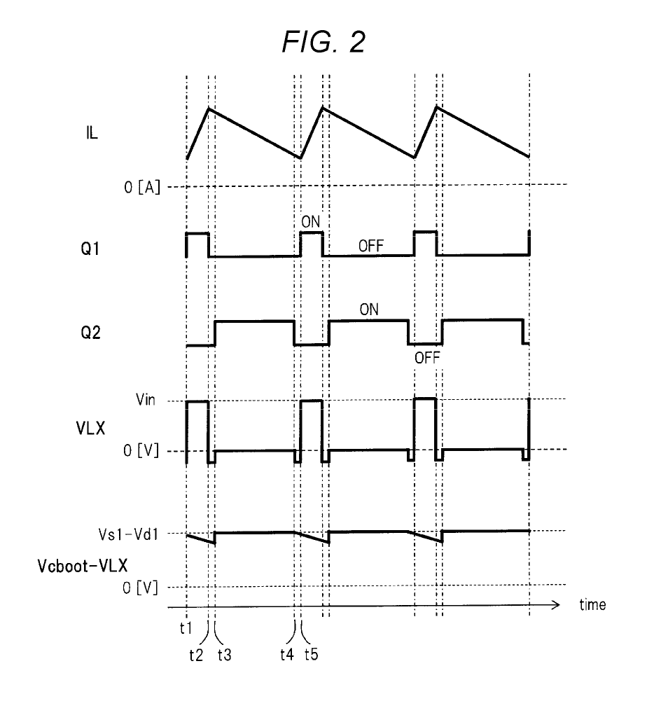

FIG. 2 is a timing diagram during a normal operation of the DC-DC converter 1 in FIG. 1. Here, the normal operation means that the load Rload is heavier than that in a light load state.

FIG. 2 illustrates an example in which the bootstrap capacitor Cboot is already charged at a time t1. In from time t1 to time t2, the high side transistor Q1 is turned on, and the low side transistor Q2 is turned off. According to this, a voltage VLX on the first terminal LX side of the inductor L1 is increased up to substantially the same potential as the input voltage Vin, and a current ILX flowing through the inductor L1 is linearly increased. In from time t1 to time t2, charging of the bootstrap capacitor Cboot is not performed, and thus, the charged voltage of the bootstrap capacitor Cboot is gradually decreased (Vcboot−VLX decreases).

Time t2 to time t3 is a dead time in which both the high side transistor Q1 and the low side transistor Q2 are turned off. The reason why the dead time is provided is to prevent a penetration current (direct to ground current). In this period, a voltage on the first terminal LX side of the inductor L1 is sharply decreased, and in addition, the charged voltage of the bootstrap capacitor Cboot is also gradually decreased. The inductor L1 cannot switch sharply the direction of a current, and thus a current is gradually decreased after the time t2.

From time t3 to time t4, the high side transistor is turned off, and the low side transistor Q2 is turned on. According to this, a voltage on the first terminal LX side of the inductor L1 has a ground level (for example, 0 V). The current (IL) flowing through the inductor L1 is gradually and continuously decreased. When the low side transistor Q2 is turned on, a voltage of the high side power supply node n2 (that is, the one terminal the bootstrap capacitor Cboot) is also decreased, under the influence of the voltage on the first terminal LX side of the inductor L1 that has the ground level, by a law of charge conservation. According to this, the bootstrap capacitor Cboot is charged through the second charging control circuit 9, whereby the bootstrap capacitor Cboot enters a fully charged state. Therefore, the charged voltage of the bootstrap capacitor Cboot is substantially constant.

Time t4 to time t5 is dead time in which both the high side transistor Q1 and the low side transistor Q2 are turned off. In this period, the charged voltage of the bootstrap capacitor Cboot is gradually decreased. Thereafter, after a time t5, the same operations as in times t1 to t5 can be repeated.

In this way, at a normal operation, the DC-DC converter 1 alternately turns on the high side transistor Q1 and the low side transistor Q2, and generates the output voltage Vout with a voltage level different from the input voltage Vin. By controlling a ratio of an ON period of the high side transistor Q1 and the low side transistor Q2, the voltage level of the output voltage Vout may be adjusted.

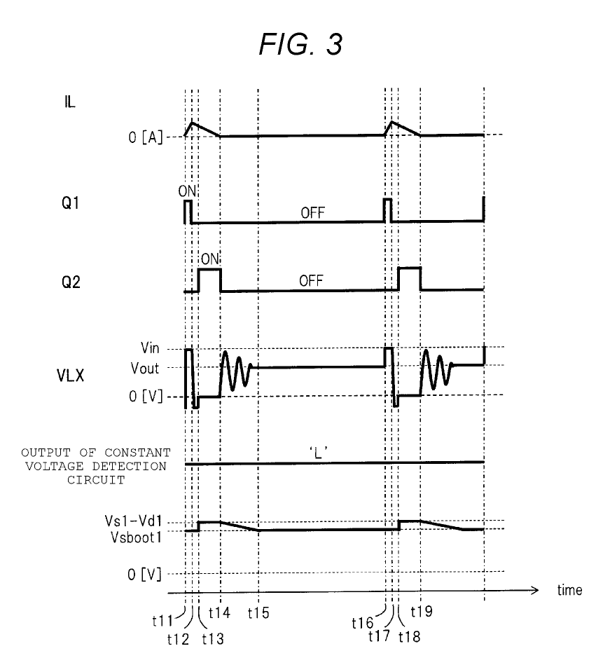

FIG. 3 is a timing diagram at the time of a light load and when a potential difference between the input voltage Vin and the output voltage Vout is higher than the first voltage. In this case, the voltage difference detection circuit 5 outputs a detection signal having a low potential which indicates the input voltage Vin is higher than the output voltage Vout by the first voltage.

At times t11 to t14, the same operations as in the times t1 to t4 in FIG. 2 are performed. At a time t14, when it is determined by the light load determination circuit 6 that a load is a light load, after the time t14, the high side transistor Q1 and the low side transistor Q2 are turned off together. According to this, the charged voltage of the bootstrap capacitor Cboot is gradually decreased.

At time t14, although the first terminal LX of the inductor L1 has a high impedance, the other terminal (second terminal) side of the inductor L1 has the output voltage Vout according to the charged voltage of an output capacitor Cout. For this reason, a voltage on the first terminal LX side of the inductor L1 vibrates greatly after time t14, and a vibration amplitude thereof is gradually decreased over time, and eventually becomes the same potential as the output voltage Vout on the second terminal side of the inductor L1.

At a time t15, when the charged voltage of the bootstrap capacitor Cboot is decreased to a predetermined voltage Vboot1, the voltage of the high side power supply node n2 is decreased, a gate-source voltage of the third transistor Q3 in the first charging control circuit 7 is increased, a current flows from the application node of the input voltage Vin to the high side power supply node n2 via the third transistor Q3, and charging of the bootstrap capacitor Cboot is performed. The third transistor Q3 operates in an active region (linear operation mode), not at a saturation region (saturated operation mode). Thus, from the time t15 to time t16 in which the high side transistor Q1 is turned on, the first charging control circuit 7 continuously charges the bootstrap capacitor Cboot, and the voltage of the high side power supply node n2 is maintained as about the voltage Vboot1. After the time t16, the same operations as the operations in the times t11 to t16 are repeated.

The first charging control circuit 7 continuously supplies a slight charging current to the bootstrap capacitor Cboot via the third transistor Q3, and charges the bootstrap capacitor Cboot. That is, the first charging control circuit 7 makes just enough current flow for charging the bootstrap capacitor Cboot, and it is possible to further reduce power consumption as compared to charging the bootstrap capacitor Cboot by turning on the low side transistor Q2.

In this way, in the present embodiment, when a load is in a state of a light load and a voltage difference between the input voltage Vin and the output voltage Vout is higher than the first voltage, the bootstrap capacitor Cboot is charged using the first charging control circuit 7, in a state in which the low side transistor Q2 is turned off.

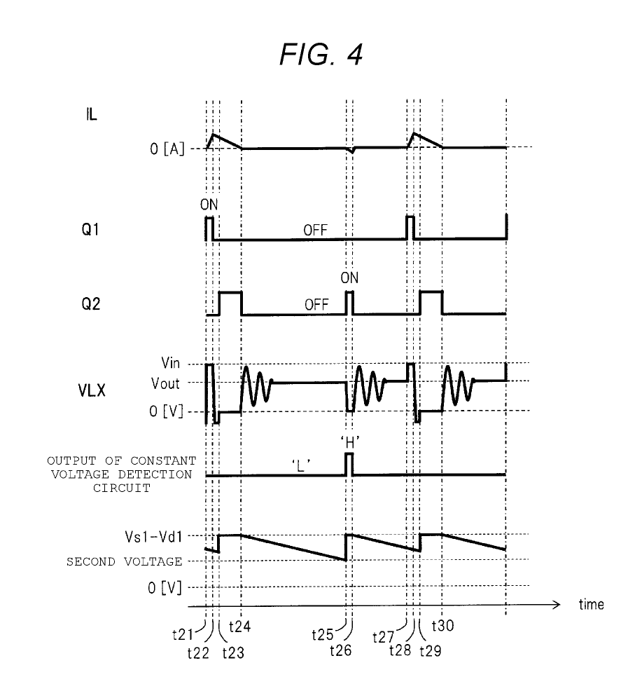

FIG. 4 is a timing diagram when a load is in a state of a light load and a voltage difference between the input voltage Vin and the output voltage Vout is equal to or lower than the first voltage. In this case, the voltage difference detection circuit 5 outputs a detection signal of a high potential which indicates that a voltage difference between the input voltage Vin and the output voltage Vout is equal to or lower than the first voltage. In this state, when the low voltage detection circuit 4 detects that the charged voltage of the bootstrap capacitor Cboot is equal to or lower than a second voltage, an output of the logic operation unit 12 becomes high. According to this, the signal processing unit 13 releases the fixed OFF signal of the low side transistor Q2.

At times t21 to t24, the same operations as at the times t11 to t14 are performed. At the time t24, when the high side transistor Q1 and the low side transistor Q2 are turned off together, the charged voltage of the bootstrap capacitor Cboot is gradually decreased. Thereafter, at the time t25, the low voltage detection circuit 4 detects that the charged voltage of the bootstrap capacitor Cboot is equal to or lower than the second voltage. According to this, the output of the logic operation unit 12 has a high potential. At this time, when it is determined that the light load determination circuit 6 is also in the light load state, the signal processing unit 13 outputs a control signal of a low potential. This control signal is inverted by an inverter, and the gate of the low side transistor Q2 has a high potential. Thus, the low side transistor Q2 is turned on just for a moment (t25 to t26), and the voltage VLX on the first terminal LX side of the inductor L1 is decreased. By a law of charge conservation, a voltage on one terminal of the bootstrap capacitor Cboot, that is, a voltage of the high side power supply node n2 is also decreased. Thus, charging of the bootstrap capacitor Cboot is performed by a voltage that is output from the DC power supply 23 via the diode D1, which are included in the second charging control circuit 9. According to this, the charged voltage of the bootstrap capacitor Cboot is quickly increased. Thereafter, after the time t25, the operations in times t21 to t25 are repeated.

ON switching of the low side transistor Q2 in the time t25 is made due to the charging of the bootstrap capacitor Cboot, and turning-on of the low side transistor Q2 is made just for a moment. When a period in which the low side transistor Q2 is turned on is lengthened, a large current flows from the inductor L1 to the low side transistor Q2 side, and the output voltage Vout is also decreased.

In addition, when a voltage difference between the input voltage Vin and the output voltage Vout is equal to or lower than the first voltage, the bootstrap capacitor Cboot is not charged by the first charging control circuit 7, and this is because there is a possibility that, when the voltage difference between the input voltage Vin and the output voltage Vout is small, the voltage of the high side power supply node n2 is not decreased very much, with respect to the voltage of the node n1 of the input voltage Vin, a source voltage is not decreased very much with respect to a gate voltage of the third transistor Q3 in the second charging control circuit 9, and a sufficient charging current does not flow into the bootstrap capacitor Cboot via the third transistor Q3.

In this way, in the present embodiment, when a load is in a state of a light load and the input voltage Vin is higher than the output voltage Vout by the first voltage, in a case that the charged voltage of the bootstrap capacitor Cboot is equal to or lower than a predetermined voltage, charging of the bootstrap capacitor Cboot is performed with using the first charging control circuit 7, in a state in which the low side transistor Q2 is turned off. According to this, charging of the bootstrap capacitor Cboot is performed with much lower power consumption than charging the bootstrap capacitor Cboot by turning on the low side transistor Q2.

In addition, when a voltage difference between the input voltage Vin and the output voltage Vout is equal to or lower than the first voltage, in a case that the charged voltage of the bootstrap capacitor Cboot is equal to or lower than the second voltage, charging of the bootstrap capacitor Cboot is performed by turning on the low side transistor Q2, and thus the bootstrap capacitor Cboot may be quickly charged.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power supply circuit, comprising:
a first transistor connected to an input voltage node;
a second transistor connected between the first transistor and a reference voltage node;
a first gate control circuit having a first power supplying node and a second power supplying node and configured to control a gate voltage of the first transistor;
a capacitor connected between the first and second power supplying nodes; and
a first control circuit configured to charge the capacitor at least while the first and second transistors are in a non-conducting state.

2. The power supply circuit according to claim 1, further comprising:
a first detection circuit configured to detect a voltage difference between a reference output voltage and an output voltage at a first end of an inductor;
a determination circuit configured to determine whether or not a load is in a light load state based on the voltage difference detected by the first detection circuit; and
a signal processing unit configured to generate signals for placing the first and second transistors in a non-conducting state when the determination circuit determines the load is in the light load state.

3. The power supply circuit according to claim 2, further comprising:
a second detection circuit configured to detect whether or not a voltage difference between the input voltage node and the first end of the inductor is at or greater than a first voltage value, wherein
the first control circuit is configured to charge the capacitor while the second detection circuit detects that the voltage difference is the first voltage value or greater.

4. The power supply circuit according to claim 1, further comprising:
a second detection circuit configured to detect whether or not a voltage difference between the input voltage node and a first end of the inductor is at or greater than a first voltage value, wherein
the first control circuit is configured to charge the capacitor while the second detection circuit detects that the voltage difference is the first voltage value or greater.

5. The power supply circuit according to claim 2, further comprising:
a third detection circuit configured to detect whether or not a charged voltage of the capacitor is a second voltage value or less, wherein
the first control circuit is configured to charge the capacitor while the third detection circuit detects that the charged voltage of the capacitor is less than or equal to the second voltage value.

6. The power supply circuit according to claim 1, further comprising:
a third detection circuit configured to detect whether or not a charged voltage of the capacitor is a second voltage value or less, wherein
the first control circuit is configured to charge the capacitor while the third detection circuit detects that the charged voltage of the capacitor is less than or equal to the second voltage value.

7. The power supply circuit according to claim 2, wherein the first control circuit is configured to charge the capacitor from the input voltage node to the first power supply node while a voltage difference between the input voltage node and the first power supplying node is higher than a predetermined voltage.

8. The power supply circuit according to claim 1, wherein the first control circuit is configured to charge the capacitor from the input voltage node to the first power supply node while a voltage difference between the input voltage node and the first power supplying node is higher than a predetermined voltage.

9. The power supply circuit according to claim 8, wherein the first control circuit includes a third transistor configured to switch a connection between the input voltage node and the first power supplying node.

10. The power supply circuit according to claim 9, wherein the first control circuit includes:
a current source connected between the input voltage node and a gate of the third transistor; and
a constant voltage source connected between the gate of the third transistor and the second power supplying node.

11. The power supply circuit according to claim 10, wherein the constant voltage source is a Zener diode.

12. The power supply circuit according to claim 1, further comprising:
a second control circuit connected between the capacitor and the reference voltage node and configured to charge the capacitor while the second transistor is in a conducting state.

13. The power supply circuit according to claim 12, further comprising:
a first detecting circuit configured to detect a voltage difference between a reference output voltage and an output voltage at a first end of an inductor;
a determination circuit configured to determine whether or not a load is in a light load state based on the voltage difference detected by the first detection circuit; and
a signal processing unit configured to generate signals for placing the first and second transistors in a non-conducting state when the determination circuit determines the load is in the light load state.

14. The power supply circuit according to claim 12, further comprising:
a second detection circuit configured to detect whether or not a voltage difference between the input voltage node and the first end of the inductor is less than or equal to a first voltage value, wherein
the second control circuit is configured to charge the capacitor while the second detection circuit detects the voltage difference less than or equal to the first voltage value.

15. The power supply circuit according to claim 12, further comprising:
a third detection circuit configured to detect whether or not a charged voltage of the capacitor is less than or equal to a second voltage value, wherein
the second control circuit charges the capacitor while the third detection circuit detects the charged voltage of the capacitor is less than or equal to the second voltage value.

16. The power supply circuit according to claim 1, further comprising:
an inductor having a second end connected between the first transistor and the second transistor; and
a second capacitor connected to a second end of the inductor.

17. A DC-DC converter, comprising:
a first transistor connected to an input voltage node;
a second transistor connected in series with the first transistor between the input voltage node and a reference voltage node;
a first gate control circuit having a first power supplying node and a second power supplying node and configured to supply a gate voltage to the first transistor, the second power supply node being electrically connected to a node between the first and second transistors;
a capacitor connected between the first and second power supplying nodes; and
a first control circuit configured to charge the capacitor while the first and second transistors are in a non-conducting state, the first control circuit including a third transistor connected between the input voltage node and the first power supplying node.

18. The DC-DC converter according to claim 17, further comprising:
a first detection circuit configured to detect a voltage difference between a reference voltage and an output voltage at a first end of an inductor.

19. The DC-DC converter according to claim 17, wherein the first gate control circuit comprises a level shift circuit and an inverter.

20. A power supply circuit, comprising:
a first transistor connected to an input voltage node;
a second transistor connected in series with the first transistor between the input voltage node and a reference voltage node;
a first gate control circuit having a first power supplying node and a second power supplying node and configured to supply a gate voltage to the first transistor, the second power supply node being electrically connected to a node between the first and second transistors;
a capacitor connected between the first and second power supplying nodes;
a first detection circuit configured to detect a voltage difference between a reference voltage and an output voltage at a first end of an inductor;
a determination circuit configured to determine whether or not a load connected to the first end of the inductor is in a light load state based on the voltage difference detected by the first detection circuit;
a signal processing unit configured to generate signals for placing the first and second transistors in a non-conducting state;
a second detection circuit configured to detect whether or not a voltage difference between the input voltage node and the output node is at or greater than a first voltage value;
a third detection circuit configured to detect whether or not a charged voltage of the capacitor is a second voltage value or less; and
a first control circuit configured to charge the capacitor when the determination circuit indicates the load is in a light load state, the first and second transistors are in the non-conducting state, the voltage difference between the input voltage node and the output node is greater than the first voltage value, and the charged voltage of the capacitor is the second voltage value of less.
